(19) United States
(12) Patent Application Publication
(10) Pub. No.: US 2026/0141142 A1
(43) Pub. Date: May 21, 2026

(54) LEVERAGING FUNCTIONAL PARAMETERS TO INFLUENCE DESIGN FOR TEST (DFT) REGISTER TRANSFER LANGUAGE (RTL)

(71) Applicant: QUALCOMM Incorporated, San Diego, CA (US)

(72) Inventor: Nikhil HERLEKAR, San Ramon, CA (US)

(21) Appl. No.: 18/951,215

(22) Filed: Nov. 18, 2024

(51) Int. Cl. G06F 30/327; G06F 30/333

(52) U.S. Cl. CPC G06F 30/327; G06F 30/333

(57) ABSTRACT

Certain aspects of the present disclosure provide a method to define at least one register transfer language (RTL) level parameter for a design for test (DFT) wrapper module including at least one DFT sub-module including an RTL logic. A number of instances of the at least one DFT sub-module may be based on a value of the at least one RTL level parameter. The at least one DFT sub-module may be used for testing a system-on-a-chip (SoC) chip.

### BACKGROUND

### Field of the Disclosure

Aspects of the present disclosure relate to techniques for configuring register transfer language (RTL) parameters for a design for test (DFT) wrapper module.

### Description of Related Art

Wireless communication devices have become smaller and more powerful as well as more capable. Increasingly users rely on wireless communication devices for a mobile phone use as well as Internet access. At the same time, devices have become smaller in size. Devices such as cellular telephones, personal digital assistants (PDAs), laptop computers, and other similar devices provide reliable service with expanded coverage areas. Such devices may be referred to as mobile stations, stations, access terminals, user terminals, subscriber units, user equipments, and similar terms. These wireless devices rely on system-on-a-chips (SoCs) to provide much of the functionality desired by users.

The SoCs are tested prior to assembly in wireless devices to ensure that the chip functions as desired within specified operating parameters. Testing the SoCs may rely on a design for test (DFT). The DFT is a process that incorporates rules and techniques for testing into a design of a SoC to facilitate testing prior to delivery.

The DFT may be used to manage test complexity, minimize development time and reduce manufacturing costs. Testing involves two major aspects: control and observation. When testing any system or device it is necessary to put the system into a known state, supply known input data (e.g., test data) and then observe the system or chip to ascertain if it performs as designed.

### SUMMARY

One aspect provides a method including defining at least one register transfer language (RTL) level parameter for a design for test (DFT) wrapper module including at least one DFT sub-module including an RTL logic. A number of instances of the at least one DFT sub-module is based on a value of the at least one RTL level parameter. The method includes using the at least one DFT sub-module for testing a system-on-a-chip (SoC) chip.

Other aspects provide: an apparatus operable, configured, or otherwise adapted to perform the aforementioned method as well as those described elsewhere herein; a non-transitory, computer-readable media comprising instructions that, when executed by one or more processor of an apparatus, cause the apparatus to perform the aforementioned method as well as those described elsewhere herein; a computer program product embodied on a computer-readable storage medium comprising code for performing the aforementioned method as well as those described elsewhere herein; and an apparatus comprising means for performing the aforementioned method as well as those described elsewhere herein. By way of example, an apparatus may comprise a processing system, a device with a processing system, or processing systems cooperating over one or more networks.

The following description and the appended figures set forth certain features for purposes of illustration.

### BRIEF DESCRIPTION OF DRAWINGS

The appended figures depict certain features of the various aspects described herein and are not to be considered limiting of the scope of this disclosure.

FIG. 1 depicts an example design for test (DFT) system, in accordance with certain aspects of the present disclosure.

FIG. 2 depicts an example DFT wrapper module of a DFT system, in accordance with certain aspects of the present disclosure.

FIG. 3 depicts a method for configuring register transfer language (RTL) parameters for a DFT wrapper module of a DFT system, in accordance with certain aspects of the present disclosure.

FIG. 4 depicts an example parameterized DFT wrapper module of a DFT system, in accordance with certain aspects of the present disclosure.

### DETAILED DESCRIPTION

Aspects of the present disclosure relate to techniques for configuring register transfer language (RTL) parameters for a design for test (DFT) wrapper module.

DFT is a set of design techniques and methodologies that are implemented during the development of a digital circuit or system to make it easier to test and verify the functionality of the device once it's built. The goal of DFT is to improve the testability of the system, which helps detect faults or defects more effectively and efficiently during manufacturing, and ensures that the device meets its functional specifications.

DFT techniques may be applied during a design phase, meaning that testing features are built into a hardware at the time the system or chip is created. This is in contrast to adding test structures after the design is completed or relying entirely on external testing methods.

The DFT techniques may be used to create a DFT wrapper module (e.g., including logic and sub-modules) based on high-level specification that is fed into a DFT computer-aided design (CAD) tool. For example, various sub-modules and logic may be wrapped in one module called as the DFT wrapper module. The high-level specification may be a way to design electronic circuits that starts with a behavioral description of a system and then automatically generates an RTL design. The high-level specification may be a proprietary CAD tool syntax that a user may feed into the DFT CAD tool and a corresponding DFT register transfer language (RTL) is generated.

Currently, different DFT wrapper modules have to be generated and used for different projects as the different projects may require different DFT logic and sub-modules associated with the different DFT wrapper modules.

Techniques proposed herein describe the use of a single DFT wrapper module for different projects. The DFT wrapper module may define one or more RTL parameters in a header of the DFT wrapper module. The RTL parameters may influence logic or sub-modules in the DFT wrapper module in such a way that the logic or the sub-modules in the DFT wrapper module may scale based on values of the RTL parameters. For example, different values of the RTL parameters may be applicable for the different projects, and the logic or sub-modules in the DFT wrapper module may get replicated or scale based on the different values of the RTL parameters for the different projects.

Particular aspects of the subject matter described in this disclosure can be implemented to realize one or more of the following potential advantages. In some examples, the described techniques may allow a same DFT wrapper module to be reused in multiple projects by changing RTL parameters values corresponding to the DFT wrapper module. The use of the same DFT wrapper module for the different projects may reduce overall maintenance time or bug fixing work corresponding to the DFT wrapper module, since a single DFT wrapper module is being used for the multiple projects.

### Example Design For Test (DFT) System

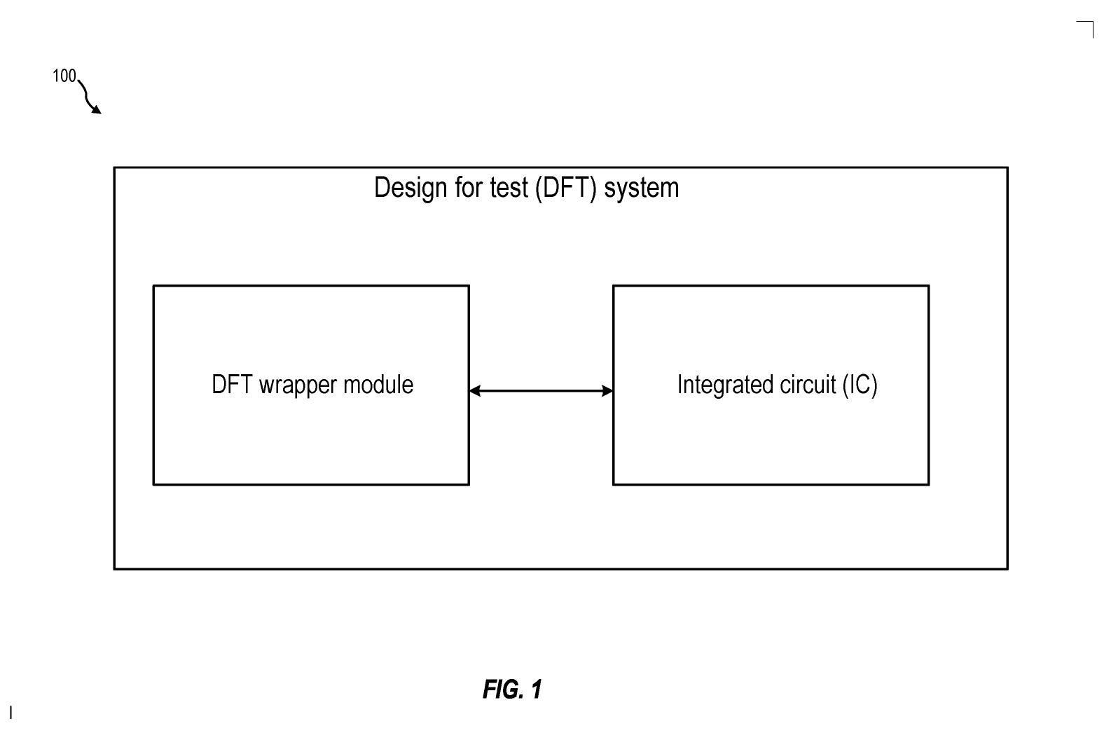

FIG. 1 depicts a diagram 100 illustrating an example design for test (DFT) system. The DFT system may include a DFT wrapper module and an integrated circuit (IC).

The DFT wrapper module may execute a set of techniques used in design and development of electronic systems, particularly the IC, to make the IC easier to test for manufacturing defects, performance issues, and functional correctness. The DFT may ensure that the IC can be thoroughly tested during and after production, improving yield, reducing costs, and increasing the reliability of a final product.

The DFT techniques may be implemented during a design phase, making testing easier and more efficient once a device (e.g., the IC) is manufactured. It involves adding extra circuitry or features that help verify the functionality of the device and its components.

Some components and techniques of the DFT system may include scan chains, a built-in self-test (BIST), a boundary scan, test access ports (TAP), a memory built-in self-test (MBIST), fault simulation tools, and/or test pattern generation.

The scan chains are a technique for testing digital circuits. Flip-flops or registers in a circuit are connected in a scan chain, allowing for easy shifting of test data in and out of a device. This enables testing of internal signals that might not otherwise be accessible.

The BIST is a method where a device includes a built-in testing mechanism that can run diagnostic tests on a circuit without needing external equipment. This is useful for checking for faults in the device during operation.

The boundary scan (joint test action group (JTAG)) standard defines a method for testing circuits through a serial communication protocol. It allows for testing of individual components (e.g., the ICs) by accessing their pins directly, even if they are embedded within a larger system.

The TAPs provide a standardized way to access and control the scan chains, allowing for easier debugging and testing of devices.

The MBIST focuses on testing memory blocks within a device. The MBIST provides a way to test for faults in memory arrays by using special circuits designed for that purpose.

In a design process, the fault simulation tools are used to model various faults that could occur in a circuit. DFT methods often include checking for high fault coverage to ensure that most types of defects are detectable during testing.

Test patterns (also called "vectors") may be generated to exercise different parts of a circuit and ensure that all possible defects or failures are detected. These patterns are created in such a way that they can be applied efficiently and provide thorough test coverage.

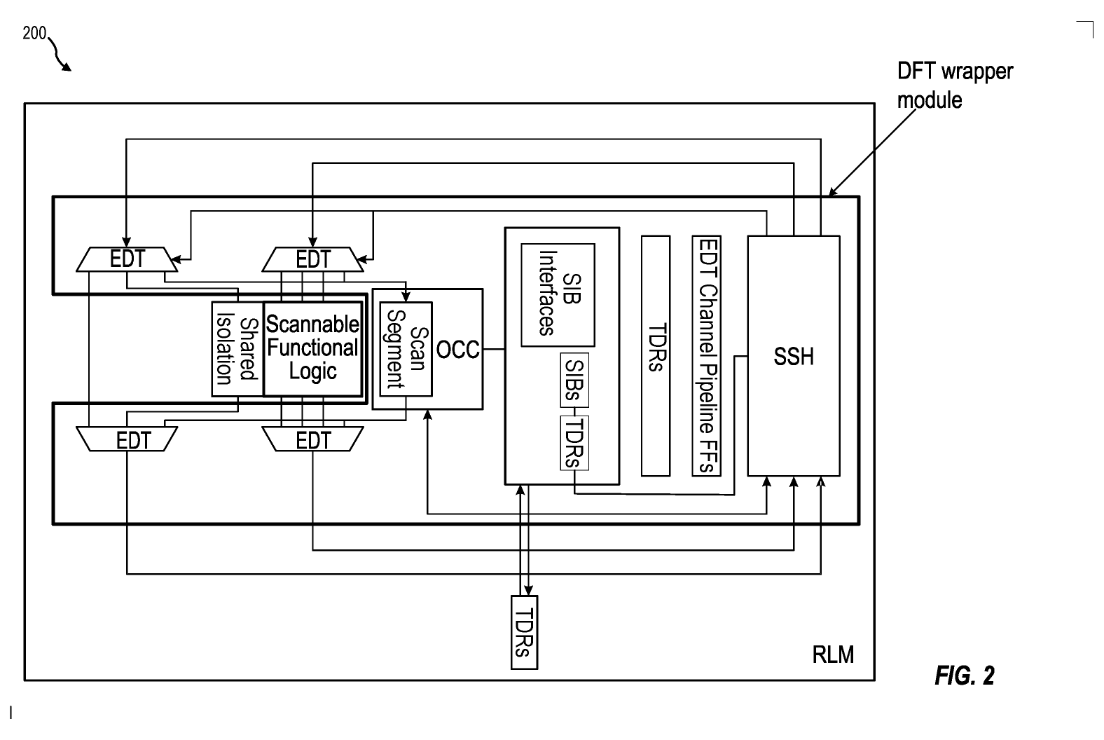

FIG. 2 depicts a diagram 200 illustrating an example DFT wrapper module. The DFT wrapper module may be logic (e.g., with certain connections) to serve a test for a region outside it, which may be a routing level module (RLM).

The DFT wrapper module may include multiple components including but not limited to ports, an on-chip clock controller (OCC), embedded deterministic tests (EDTs), a streaming scan network host (SSH), test data registers (TDRs), segment insertion bits (SIBs), SIB interfaces, scan segments, a scannable functional logic, shared isolation, and EDT channel pipeline flip-flops.

The OCC may be a component integrated into a system on a chip (SoC) that manages distribution and timing of clock signals within the SoC. The SoC may be an IC that combines multiple components of an electronic device onto a single chip. The clock signals are essential for synchronizing an operation of various parts of the SoC, such as processor cores, memory controllers, and peripheral devices.

The OCC may generate internal clock signals or manage clock signals derived from an external source (e.g., an external crystal oscillator). These clocks drive a timing of a processor and other components on the SoC. The OCC may distribute the clock signals to various functional units within the SoC, such as processor cores, memory, I/O interfaces, and other subsystems. The OCC may ensure that each component gets a necessary clock frequency to operate correctly. The OCC may enable or disable specific clock domains, which helps save power when certain parts of the SoC are idle.

The EDTs refer to a set of tests embedded directly within a system or chip design, aimed at verifying the functional correctness of hardware and detecting faults. The term "deterministic" emphasizes that these tests are designed to produce predictable, repeatable results that can be used to ensure that a system functions as expected under specific conditions. By embedding tests during the design and manufacturing phases, issues can be detected early, which is crucial for maintaining high yields in production and for ensuring that devices meet their specifications before being deployed.

The SSH may be a reference to a network scanning or a monitoring system in which hosts are involved in real-time, continuous scanning and their results or data are streamed likely over a secure shell connection for secure communication.

A TDR may be a specialized register used, particularly in a context of boundary scan testing (e.g., used in circuit board testing). The TDR may facilitate shifting of test data into and out of a device for testing purposes. The TDR may be a shift register that can hold data for testing or debugging, allowing users to inject test patterns into a circuit for checking functionality and read back outputs or response data to analyze the circuit's behavior and performance.

The TDR may be part of a larger test access port (TAP) interface, such as the one defined by JTAG standard. In JTAG, the TDR is part of a TAP controller. The boundary scan cells in an IC may be connected to the TDR, and during a boundary scan operation, test patterns are sent into these cells and the results are captured in the TDR to be analyzed.

The SIBs are a concept used in digital systems, specifically in the context of embedded systems and SoC designs, where they are used for debugging, testing, and fault isolation. The SIBs may refer to specific bits or control flags that are inserted into a data stream, a memory segment, or a control path to enable, disable, or control the behavior of certain segments of a system or device during testing. These bits are usually placed at key points in the design or in a data packet structure, are used for enabling specific tests or diagnostic routines within a segmented system, allowing selective activation or deactivation of different sections of hardware or software, and helping to identify faults by controlling which segment (or module) of the system is being tested.

The scan segments may refer to portions of a scan chain or scan path in a digital circuit or IC design that are used for applying test vectors, scanning in data, and scanning out the results. A scan chain is a series of flip-flops (or other types of sequential logic elements) connected in a chain-like manner, where the output of one flip-flop is connected to the input of the next.

The scan chain is a series of scan flip-flops inserted into the IC design to convert normal operational paths of logic into a serial shift register for easier testing. A scan segment is a group or block of these scan flip-flops, or a subset of the scan chain, that is used for testing purposes. The scan segments may correspond to different functional areas or sections of the digital circuit.

The scannable functional logic may refer to a functional logic in a digital circuit that has been modified or designed in a way that it can be scanned, that is, test data can be shifted in and out of the logic during a test procedure. This is done by embedding scan flip-flops or other scan-related structures into the design. These modifications enable the system to be more easily tested.

The shared isolation in the context of DFT refers to a technique used to improve the testability of ICs or SoCs by isolating different functional blocks or segments of a design during the testing process while sharing resources like test access ports or scan chains. The primary goal of the shared isolation is to minimize the area and overhead introduced by DFT structures (like scan chains) and to improve test efficiency by selectively isolating parts of the circuit for testing. It allows parts of the circuit to be independently tested without the need for a separate scan chain or test access for each block, making the testing process more efficient and reducing the complexity of the design.

The EDT channel pipeline flip-flops are a specialized type of flip-flops used in the context of the EDT, which is a technique used in the DFT to enhance the testability and observability of complex systems, especially in embedded systems or SoC designs. The flip-flops, placed at various stages of a data pipeline, allow for controlled, deterministic data flow, enabling the observation of system behavior at multiple points in the pipeline. The flip-flops are part of a pipeline structure designed to improve the testability and timing of data flow during test operations, allowing for deterministic testing and faster fault isolation.

### Example Functional Parameters to Influence Design For Test (DFT) Register Transfer Language (RTL) For Intellectual Property (IP) Reuse

Design for test (DFT) consists of integrated circuit (IC) design techniques that add testability features to a hardware product design. The added features make it easier to develop and apply manufacturing tests to a designed hardware. The purpose of the manufacturing tests is to validate that a product hardware contains no manufacturing defects that could adversely affect the product's correct functioning.

DFT logic may be created using high-level user specifications for DFT computer-aided design (CAD) tools. The specification may be a proprietary CAD tool syntax that a user may feed into a CAD tool and a corresponding DFT register transfer language (RTL) is written accompanied by a corresponding test model.

The DFT RTL may be integrated into a functional RTL and synthesized to a netlist. The functional RTL may refer to description of digital circuits in terms of the flow of signals (data) between hardware registers and logical operations performed on that data. The RTL is a hardware description abstraction level used in digital design, typically written in hardware description languages (HDLs) like Verilog. The netlist may be a textual representation of an electronic circuit that lists all of its components (such as transistors, resistors, and capacitors) and their connections, or "nets." In digital design, netlists describe the interconnections of circuit elements, usually after a design has been synthesized from a high-level description, like the RTL. Netlists are used in the design and manufacturing of the digital circuits, including application-specific integrated circuits (ASICs) and field programmable gate arrays (FPGAs).

The CAD tool written DFT RTL may lack any feature to create its multiple instances. An instance in circuit design is a copy or occurrence of a component or sub circuit within a larger design. It represents a specific implementation of a part, which can be used and configured multiple times throughout a project.

For example, a DFT instrument such as a test data register (TDR) may be instantiated in the functional RTL once, but can be replicated in a generate statement using a parameter value that exists in the functional RTL. The method may scale the DFT RTL with the functional RTL either within the functional RTL or in a standalone DFT instrument wrapper.

One way to implement the DFT RTL is to repeat a high-level DFT specification for the CAD tool to write out multiple DFT instruments and then integrate them. The functional RTL may be written such that the functional RTL may scale according to a project requirement. However, it may not be possible to scale the DFT RTL because the CAD tool cannot write out a parameterized RTL.

Techniques proposed herein describe that a DFT CAD tool written RTL may be pushed into a RTL construct that will scale with functional RTL parameter values. For example, a DFT wrapper module may define one or more RTL parameters in a header of the DFT wrapper module. The RTL parameters may influence logic or sub-modules in the DFT wrapper module in such a way that the logic or the sub-modules in the DFT wrapper module may scale with a functional RTL.

The DFT wrapper module may be instantiated in the functional RTL for a DFT. For example, a number of instances of a first sub-module of the DFT wrapper module may be based on a value of a first RTL parameter and a number of instances of a second sub-module of the DFT wrapper module may be based on a value of a second RTL parameter. The values of the first RTL parameter and the second RTL parameter may be different for different projects.

Particular aspects of the subject matter described in this disclosure can be implemented to realize one or more of the following potential advantages. In some examples, the described techniques may allow a same DFT wrapper module (e.g., which is an intellectual property (IP)) to be reused in multiple projects by changing RTL parameters values corresponding to the DFT wrapper module. The use of the same DFT wrapper module for the different projects may reduce overall maintenance time or bug fixing work corresponding to the DFT wrapper module since a single DFT wrapper module is being used for the multiple projects.

In chip design, IP stands for intellectual property core, which is a reusable block of logic or data used to create a semiconductor chip. IP cores can be used to make ASICs, FPGAs, or other types of integrated circuits. IP cores are the intellectual property of a company or person, and can be licensed to other parties or used by the original owner. Semiconductor companies can use IP cores to: speed up the design process, reduce development costs, and streamline workflows.

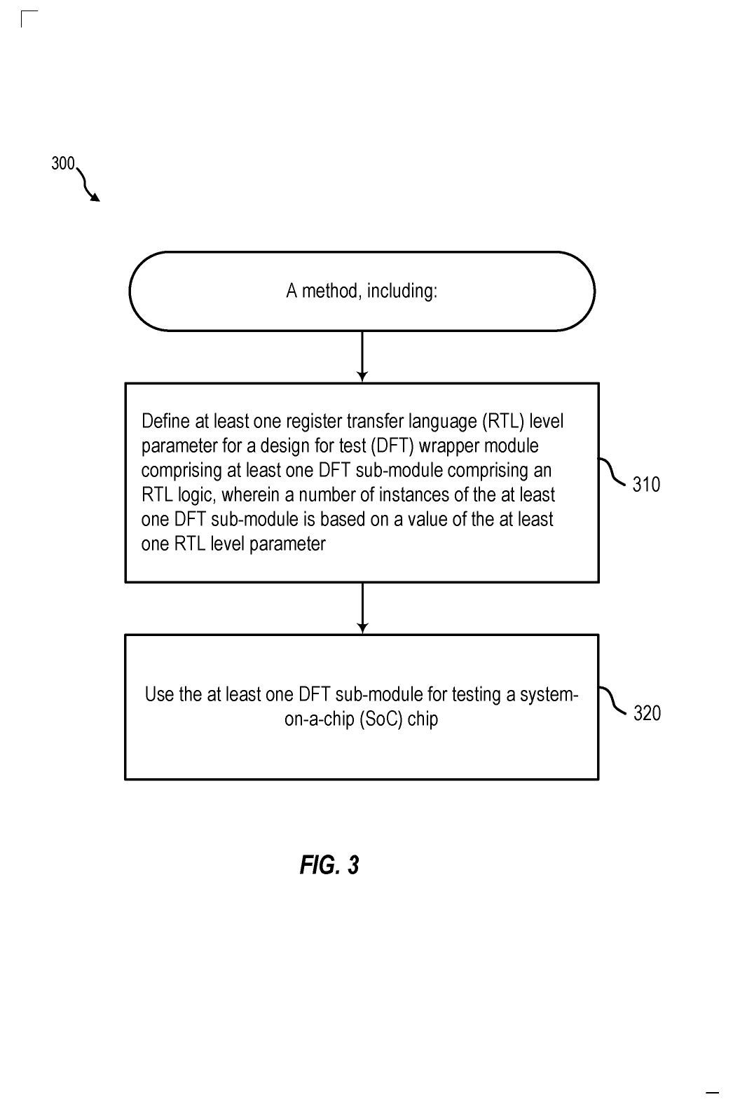

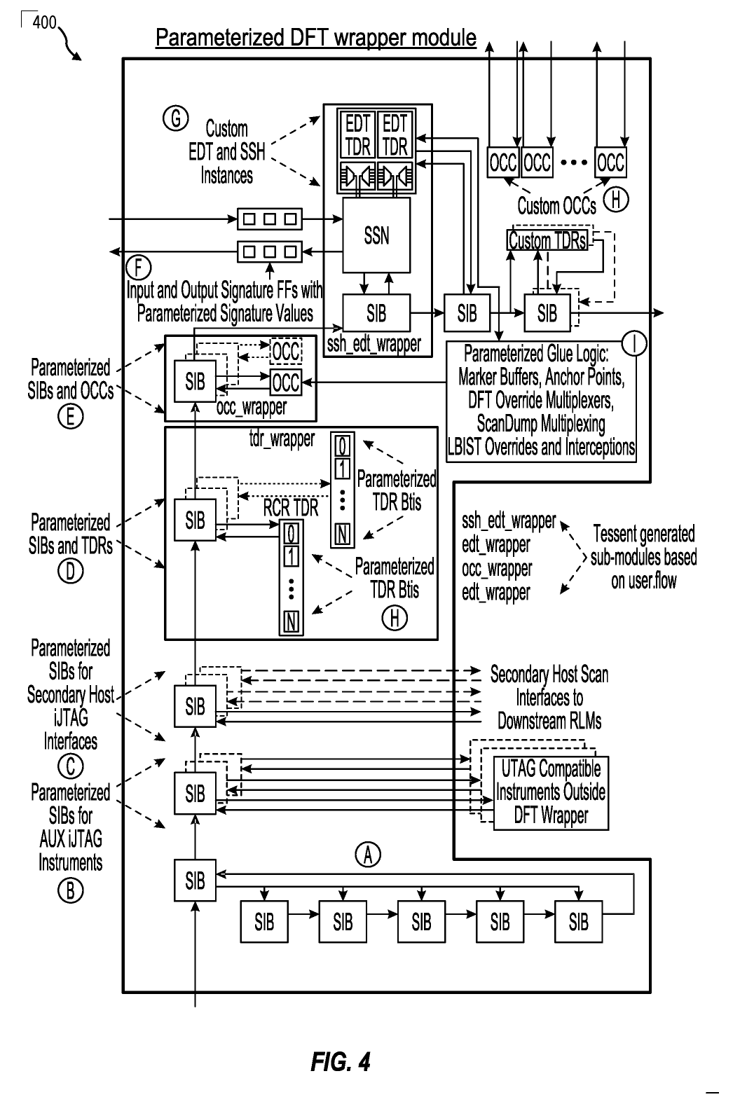

The techniques proposed herein may be further understood with reference to FIG. 3 - FIG. 4.

FIG. 3 depicts a method 300 for configuring RTL parameters for a DFT wrapper module.

Method 300 begins at 310 with defining at least one RTL level parameter (also called as an RTL parameter) for the DFT wrapper module including at least one DFT sub-module including an RTL logic. A number of instances of the at least one DFT sub-module may be based on a value of the at least one RTL level parameter.

Method 300 begins at 320 with using the at least one DFT sub-module for testing a system-on-a-chip (SoC) chip.

In certain aspects, the DFT wrapper module may include multiple DFT sub-modules.

In certain aspects, the at least one RTL level parameter is associated with the multiple DFT sub-modules, and the number of instances of each of the multiple DFT sub-modules is based on the value of the at least one RTL level parameter.

In certain aspects, a size of each of the multiple DFT sub-modules is based on the value of the at least one RTL level parameter.

In certain aspects, the method 300 further includes configuring a default value of the at least one RTL level parameter in the DFT wrapper module.

In certain aspects, the method 300 further includes assigning a new value for the at least one RTL parameter in the DFT wrapper module, wherein the new value overrides the default value.

In certain aspects, the method 300 further includes using the default value for the at least one RTL parameter in the DFT wrapper module based on an absence of any other value for the at least one RTL parameter.

In certain aspects, the method 300 further includes instantiating one or more DFT sub-modules in the DFT wrapper module with different values of the at least one RTL level parameter for two unique instances of the DFT wrapper module in the SoC chip.

In certain aspects, the method 300 further includes determining the value of the at least one RTL level parameter based on the SoC chip, and customizing the DFT wrapper module based on the value of the at least one RTL level parameter.

In certain aspects, the DFT wrapper module may include zero or more DFT sub-modules such as an on-chip clock controller (OCC).

In certain aspects, the DFT wrapper module may include zero or more DFT sub-modules such as a segment insertion bit (SIB).

In certain aspects, the DFT wrapper module may include zero or more DFT sub-modules such as a test data register (TDR).

In certain aspects, the DFT wrapper module may include zero or more DFT sub-modules such as an embedded deterministic test (EDT).

In certain aspects, the DFT wrapper module may include zero or more DFT sub-modules such as a streaming scan network host (SSH).

In certain aspects, the DFT wrapper module may include zero or more DFT sub-modules such as a streaming scan network (SSN).

In certain aspects, the DFT wrapper module may include one or more DFT ports.

In certain aspects, the method 300 further includes defining at least one functional parameter to scale one or more DFT sub-modules in the DFT wrapper module.

Note that FIG. 3 is just one example of a method, and other methods including fewer, additional, or alternative steps are possible consistent with this disclosure.

FIG. 4 depicts a diagram 400 illustrating an example parameterized DFT wrapper module. The parameterized DFT wrapper module may define RTL parameters in its header. The RTL parameters may correspond to variables with integer values.

In certain aspects, an RTL parameter may be associated with one or more DFT sub-modules of the parameterized DFT wrapper module and a number of instances of the one or more DFT sub-modules may be determined based on an RTL parameter value. For example, the RTL parameters may influence internal logic or the DFT sub-modules such as OCCs, SIBs, TDRs, EDTs, SSHs, and/or SSNs of the parameterized DFT wrapper module to scale based on values of the RTL parameters.

In certain aspects, the parameterized DFT wrapper module may include SIBs (e.g., “A” in FIG. 4).

In certain aspects, the parameterized DFT wrapper module may include parameterized SIBs for auxiliary internal joint test action group (iJTAG) instruments (e.g., “B” in FIG. 4). For example, a number of parameterized SIBs may be generated based on a value of an RTL parameter corresponding to SIBs for the auxiliary group iJTAG instruments. These parameterized SIBs may be associated with iJTAG compatible instruments (e.g., which may be outside of the parameterized DFT wrapper module).

In certain aspects, the parameterized DFT wrapper module may include parameterized SIBs for secondary host iJTAG interfaces (e.g., “C” in FIG. 4). For example, a number of parameterized SIBs may be generated based on a value of an RTL parameter corresponding to SIBs for the secondary host iJTAG interfaces. These parameterized SIBs may be associated with secondary host scan interfaces to downstream routing level modules (RLMs).

In certain aspects, the parameterized DFT wrapper module may include a TDR wrapper including parameterized SIBs and TDRs (e.g., “D” in FIG. 4). For example, a number of parameterized SIBs and TDRs may be generated based on values of one or more RTL parameters corresponding to the SIBs and the TDRs.

In certain aspects, the parameterized DFT wrapper module may include an OCC wrapper including parameterized SIBs and OCCs (e.g., “E” in FIG. 4). For example, a number of parameterized SIBs and OCCs may be generated based on values of one or more RTL parameters corresponding to the SIBs and the OCCs.

In certain aspects, the parameterized DFT wrapper module may include input/output signature flip-flops with parameterized signature values (e.g., “F” in FIG. 4).

In certain aspects, the parameterized DFT wrapper module may include an SSH EDT wrapper including custom EDT and SSH instances (e.g., “G” in FIG. 4).

In certain aspects, the parameterized DFT wrapper module may include custom OCCs (e.g., “H” in FIG. 4).

In certain aspects, the parameterized DFT wrapper module may include parameterized glue logic such as marker buffers, anchor points, DFT override multiplexers, scan dump multiplexing, and logic built-in self-test (LBIST) overrides and interceptions (e.g., “I” in FIG. 4). The parameterized glue logic may be associated with the parameterized SIBs and OCCs. The parameterized glue logic may be associated with EDT TDRs.

In certain aspects, a user may bind RTL parameter values at an instance of the DFT wrapper module in a functional RTL.

In certain aspects, RTL parameter values may override default DFT wrapper module parameter values in a header of the parameterized DFT wrapper module. For example, an assignment of a value to an RTL parameter may override a default value of the RTL parameter from outside of the DFT wrapper module at its instance in a higher level of logical hierarchy.

In certain aspects, an absence of a binding value to an RTL parameter may result into a default value assigned to each RTL parameter defined in a header of the DFT wrapper module. For example, default RTL parameter values within the DFT wrapper module may be used in case of the absence of overriding RTL parameter values at the instance of the DFT wrapper module in the higher level of logical hierarchy.

In certain aspects, a user may instantiate one or more DFT wrapper modules within a same functional RTL with different values for RTL parameters for a particular project or for variety of projects.

In certain aspects, there may be instances of the one or more DFT sub-modules in a same DFT wrapper module with different values of at least one RTL parameter for two unique instances of the DFT wrapper module in a same SoC.

In certain aspects, at a time of simulation compilation or during synthesis, RTL parameter values may be expanded such that logic within the DFT wrapper module may be customized for a project specific functional RTL.

In certain aspects, a DFT wrapper module RTL may not change for a variety of projects because logic of the DFT wrapper module may be rendered to a parameter value dynamically at a time of compilation or synthesis. This IP reuse may increase an efficiency of an RTL maintenance, bug fixing and verification.

In certain aspects, one or more DFT wrapper module ports may be bussed using same RTL parameters. So, the DFT wrapper module instance port map may remain identical across multiple projects.

### Example Clauses

### Implementation examples are described in the following numbered clauses:

Clause 1: A method, comprising: defining at least one register transfer language (RTL) level parameter for a design for test (DFT) wrapper module comprising at least one DFT sub-module comprising an RTL logic, wherein a number of instances of the at least one DFT sub-module is based on a value of the at least one RTL level parameter; and using the at least one DFT sub-module for testing a system-on-a-chip (SoC) chip.

Clause 2: The method of clause 1, wherein the DFT wrapper module comprises multiple DFT sub-modules.

Clause 3: The method of any one of clauses 1-2, wherein the at least one RTL level parameter is associated with the multiple DFT sub-modules; and the number of instances of each of the multiple DFT sub-modules is based on the value of the at least one RTL level parameter.

Clause 4: The method of clause 2, wherein a size of each of the multiple DFT sub-modules is based on the value of the at least one RTL level parameter.

Clause 5: The method of any one of clauses 1-4, further comprising configuring a default value of the at least one RTL level parameter in the DFT wrapper module.

Clause 6: The method of clause 5, further comprising assigning a new value for the at least one RTL parameter in the DFT wrapper module, wherein the new value overrides the default value.

Clause 7: The method of clause 5, further comprising using the default value for the at least one RTL parameter in the DFT wrapper module based on an absence of any other value for the at least one RTL parameter.

Clause 8: The method of any one of clauses 1-7, further comprising instantiating one or more DFT sub-modules in the DFT wrapper module with different values of the at least one RTL level parameter for two unique instances of the DFT wrapper module in the SoC chip.

Clause 9: The method of any one of clauses 1-8, further comprising: determining the value of the at least one RTL level parameter based on the SoC chip; and customizing the DFT wrapper module based on the value of the at least one RTL level parameter.

Clause 10: The method of any one of clauses 1-9, wherein the DFT wrapper module comprises zero or more DFT sub-modules comprising on-chip clock controllers (OCCs).

Clause 11: The method of any one of clauses 1-10, wherein the DFT wrapper module comprises zero or more DFT sub-modules comprising segment insertion bits (SIBs).

Clause 12: The method of any one of clauses 1-11, wherein the DFT wrapper module comprises zero or more DFT sub-modules comprising test data registers (TDRs).

Clause 13: The method of any one of clauses 1-12, wherein the DFT wrapper module comprises zero or more DFT sub-modules comprising embedded deterministic tests (EDTs).

Clause 14: The method of any one of clauses 1-13, wherein the DFT wrapper module comprises zero or more DFT sub-modules comprising streaming scan network hosts (SSHs).

Clause 15: The method of any one of clauses 1-14, wherein the DFT wrapper module comprises one or more DFT ports.

Clause 16: The method of any one of clauses 1-15, further comprising defining at least one functional parameter to scale one or more DFT sub-modules in the DFT wrapper module.

Clause 17: An apparatus, comprising: at least one memory comprising instructions; and one or more processors configured, individually or in any combination, to execute the instructions and cause the apparatus to perform a method in accordance with any one of Clauses 1-16.

Clause 18: An apparatus, comprising means for performing a method in accordance with any one of Clauses 1-16.

Clause 19: A non-transitory computer-readable medium comprising executable instructions that, when executed by one or more processors of an apparatus, cause the apparatus to perform a method in accordance with any one of Clauses 1-16.

Clause 20: A computer program product embodied on a computer-readable storage medium comprising code for performing a method in accordance with any one of Clauses 1-16.

### Additional Considerations

The preceding description is provided to enable any person skilled in the art to practice the various aspects described herein. The examples discussed herein are not limiting of the scope, applicability, or aspects set forth in the claims. Various modifications to these aspects will be readily apparent to those skilled in the art, and the general principles defined herein may be applied to other aspects. For example, changes may be made in the function and arrangement of elements discussed without departing from the scope of the disclosure. Various examples may omit, substitute, or add various procedures or components as appropriate. For instance, the methods described may be performed in an order different from that described, and various actions may be added, omitted, or combined. Also, features described with respect to some examples may be combined in some other examples. For example, an apparatus may be implemented or a method may be practiced using any number of the aspects set forth herein. In addition, the scope of the disclosure is intended to cover such an apparatus or method that is practiced using other structure, functionality, or structure and functionality in addition to, or other than, the various aspects of the disclosure set forth herein. It should be understood that any aspect of the disclosure disclosed herein may be embodied by one or more elements of a claim.

The various illustrative logical blocks, modules and circuits described in connection with the present disclosure may be implemented or performed with a general purpose processor, a digital signal processor (DSP), an ASIC, a field programmable gate array (FPGA) or other programmable logic device (PLD), discrete gate or transistor logic, discrete hardware components, or any combination thereof designed to perform the functions described herein. A general-purpose processor may be a microprocessor, but in the alternative, the processor may be any commercially available processor, controller, microcontroller, or state machine. A processor may also be implemented as a combination of computing devices, e.g., a combination of a DSP and a microprocessor, a plurality of microprocessors, one or more microprocessors in conjunction with a DSP core, a system on a chip (SoC), or any other such configuration.

As used herein, “a processor,” “at least one processor” or “one or more processors” generally refers to a single processor configured to perform one or multiple operations or multiple processors configured to collectively perform one or more operations. In the case of multiple processors, performance the one or more operations could be divided amongst different processors, though one processor may perform multiple operations, and multiple processors could collectively perform a single operation. Similarly, “a memory,” “at least one memory” or “one or more memories” generally refers to a single memory configured to store data and/or instructions, multiple memories configured to collectively store data and/or instructions.

As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

As used herein, the term “determining” encompasses a wide variety of actions. For example, “determining” may include calculating, computing, processing, deriving, investigating, looking up (e.g., looking up in a table, a database or another data structure), ascertaining and the like. Also, “determining” may include receiving (e.g., receiving information), accessing (e.g., accessing data in a memory) and the like. Also, “determining” may include resolving, selecting, choosing, establishing and the like.

The methods disclosed herein comprise one or more actions for achieving the methods. The method actions may be interchanged with one another without departing from the scope of the claims. In other words, unless a specific order of actions is specified, the order and/or use of specific actions may be modified without departing from the scope of the claims. Further, the various operations of methods described above may be performed by any suitable means capable of performing the corresponding functions. The means may include various hardware and/or software component(s) and/or module(s), including, but not limited to a circuit, an application specific integrated circuit (ASIC), or processor.

The following claims are not intended to be limited to the aspects shown herein, but are to be accorded the full scope consistent with the language of the claims. Within a claim, reference to an element in the singular is not intended to mean “one and only one” unless specifically so stated, but rather “one or more.” Unless specifically stated otherwise, the term “some” refers to one or more. No claim element is to be construed under the provisions of 35 U.S.C. §112(f) unless the element is expressly recited using the phrase “means for”. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims.

Claims:

1. An apparatus, comprising:
a memory comprising instructions; and
one or more processors, individually or collectively, configured to execute the instructions and cause the apparatus to:
define at least one register transfer language (RTL) level parameter for a design for test (DFT) wrapper module comprising at least one DFT sub-module comprising an RTL logic, wherein a number of instances of the at least one DFT sub-module is based on a value of the at least one RTL level parameter; and
use the at least one DFT sub-module for testing a system-on-a-chip (SoC) chip.

2. The apparatus of claim 1, wherein the DFT wrapper module comprises multiple DFT sub-modules.

3. The apparatus of claim 2, wherein:
the at least one RTL level parameter is associated with the multiple DFT sub-modules; and
the number of instances of each of the multiple DFT sub-modules is based on the value of the at least one RTL level parameter.

4. The apparatus of claim 2, wherein a size of each of the multiple DFT sub-modules is based on the value of the at least one RTL level parameter.

5. The apparatus of claim 1, wherein the one or more processors, individually or collectively, are configured to execute the instructions and cause the apparatus to configure a default value of the at least one RTL level parameter in the DFT wrapper module.

6. The apparatus of claim 5, wherein the one or more processors, individually or collectively, are configured to execute the instructions and cause the apparatus to assign a new value for the at least one RTL parameter in the DFT wrapper module, wherein the new value overrides the default value.

7. The apparatus of claim 5, wherein the one or more processors, individually or collectively, are configured to execute the instructions and cause the apparatus to use the default value for the at least one RTL parameter in the DFT wrapper module based on an absence of any other value for the at least one RTL parameter.

8. The apparatus of claim 1, wherein the one or more processors, individually or collectively, are configured to execute the instructions and cause the apparatus to instantiate one or more DFT sub-modules in the DFT wrapper module with different values of the at least one RTL level parameter for two unique instances of the DFT wrapper module in the SoC chip.

9. The apparatus of claim 1, wherein the one or more processors, individually or collectively, are configured to execute the instructions and cause the apparatus to:
determine the value of the at least one RTL level parameter based on the SoC chip; and
customize the DFT wrapper module based on the value of the at least one RTL level parameter.

10. The apparatus of claim 1, wherein the DFT wrapper module comprises zero or more DFT sub-modules comprising on-chip clock controllers (OCCs).

11. The apparatus of claim 1, wherein the DFT wrapper module comprises zero or more DFT sub-modules comprising segment insertion bits (SIBs).

12. The apparatus of claim 1, wherein the DFT wrapper module comprises zero or more DFT sub-modules comprising test data registers (TDRs).

13. The apparatus of claim 1, wherein the DFT wrapper module comprises zero or more DFT sub-modules comprising embedded deterministic tests (EDTs).

14. The apparatus of claim 1, wherein the DFT wrapper module comprises zero or more DFT sub-modules comprising streaming scan network hosts (SSHs).

15. The apparatus of claim 1, wherein the DFT wrapper module comprises one or more DFT ports.

16. The apparatus of claim 1, wherein the one or more processors, individually or collectively, are configured to execute the instructions and cause the apparatus to define at least one functional parameter to scale one or more DFT sub-modules in the DFT wrapper module.

17. A method, comprising:
defining at least one register transfer language (RTL) level parameter for a design for test (DFT) wrapper module comprising at least one DFT sub-module comprising an RTL logic, wherein a number of instances of the at least one DFT sub-module is based on a value of the at least one RTL level parameter; and
using the at least one DFT sub-module for testing a system-on-a-chip (SoC) chip.

18. The method of claim 17, wherein the DFT wrapper module comprises multiple DFT sub-modules.

19. The method of claim 18, wherein:
the at least one RTL level parameter is associated with the multiple DFT sub-modules; and
the number of instances of each of the multiple DFT sub-modules is based on the value of the at least one RTL level parameter.

20. A non-transitory computer-readable medium comprising instructions that, when executed by one or more processors, cause the one or more processors to perform a method, comprising:
defining at least one register transfer language (RTL) level parameter for a design for test (DFT) wrapper module comprising at least one DFT sub-module comprising an RTL logic, wherein a number of instances of the at least one DFT sub-module is based on a value of the at least one RTL level parameter; and
using the at least one DFT sub-module for testing a system-on-a-chip (SoC) chip.
